(19) United States
(12) Patent Application Publication
(10) Pub. No.: US 2010/0012172 A1
(43) Pub. Date: Jan. 21, 2010

(54) Photovoltaic Modules Manufactured Using Monolithic Module Assembly Techniques

(75) Inventors: David H. Meakin, Albuquerque, NM (US); James M. Gee, Albuquerque, NM (US); Sysavanh Southimath, Albuquerque, NM (US); Brian Murphy, Albuquerque, NM (US); John Telle, Albuquerque, NM (US); Andrew Mark Mitchell, Albuquerque, NM (US)

Correspondence Address: PEACOCK MYERS, P.C., 201 THIRD STREET, N.W., SUITE 1340, ALBUQUERQUE, NM, 87102, US

(73) Assignee: Advent Solar, Inc., Albuquerque, NM (US)

(21) Appl. No.: 12/432,706

(22) Filed: Apr. 29, 2009

Related U.S. Application Data
(60) Provisional application No. 61/048,898, filed on Apr. 29, 2008.
(60) Provisional application No. 61/093,673, filed on Sep. 2, 2008.

(51) Int. Cl. H01L 31/048; H01L 31/042

(52) U.S. Cl. 136/251; 136/244

(57) ABSTRACT

Photovoltaic modules comprising back-contact solar cells manufactured using monolithic module assembly techniques comprising a flexible circuit comprising a back sheet and a patterned metallization. The module may comprise busses in electrical contact with the patterned metallization to extract the current. The module may alternatively comprise multilevel metallizations. Interlayer dielectric comprising islands or dots relieves stresses due to thermal mismatch. The use of multiple cord plates enables flexible circuit layouts, thus optimizing the module. The modules preferably comprise a thermoplastic encapsulant and/or hybrid adhesive/solder materials. An ultrathin moisture barrier enables roll-to-roll processing.

### CROSS-REFERENCE TO RELATED APPLICATIONS

This application claims the benefit of the filing of U.S. Provisional Patent Application Ser. No. 61/048,898, entitled “Photovoltaic Modules using Monolithic Module Assembly”, filed on Apr. 29, 2008, and U.S. Provisional Patent Application Ser. No. 61/093,673, entitled “Photovoltaic Modules using Monolithic Module Assembly Techniques”, filed on Sep. 2, 2008, and the specifications thereof are incorporated herein by reference.

### BACKGROUND OF THE INVENTION

1. Field of the Invention (Technical Field)

The present invention comprises methods for manufacturing solar cell modules using monolithic module assembly configurations and methods.

2. Description of Related Art

Note that the following discussion refers to a number of publications by author(s) and year of publication, and that due to recent publication dates certain publications are not to be considered as prior art vis-à-vis the present invention. Discussion of such publications herein is given for more complete background and is not to be construed as an admission that such publications are prior art for patentability determination purposes.

Crystalline-silicon photovoltaic solar cells are electrically connected into a circuit to produce voltages acceptable for system performance. The solar cell circuit also provides other necessary functions like bypass diodes to limit internal heating when a solar cell in the circuit is shaded. A photovoltaic module encloses the solar cell circuit in a package for environmental protection. The photovoltaic module typically encapsulates the solar cell circuit with a glass cover, polymer, and a backsheet. The encapsulation is typically performed in a lamination step that applies pressure and temperature on the glass/polymer/cell/polymer/backsheet layer structure while under vacuum. The photovoltaic module frequently includes a frame around the encapsulated cell assembly for ease of handling, mechanical strength, and for locations to mount the photovoltaic module. The photovoltaic module typically also includes a “junction box” where electrical connection to other components of the complete photovoltaic system (“cables”) is made.

The typical fabrication sequence for photovoltaic modules is assembly of the solar cell circuit, assembly of the layered structure (glass, polymer, solar cell circuit, polymer, backsheet), and lamination of the layered structure. The final steps include installation of the module frame and junction box, and testing of the module. The solar cell circuit is typically manufactured using automated tools (“stringer/tabbers”) that connect the solar cells in electrical series with copper (Cu) flat ribbon wires (“interconnects”). Several strings of series-connected solar cells are then electrically connected with wide Cu ribbons (“busses”) to complete the circuit. These busses also bring the current to the junction box from several points in the circuit for the bypass diodes and for connection to the cables. The majority of solar cells today have contacts on opposite surfaces.

Limitations of this process include the following:
The process of electrically connecting solar cells in series is difficult to automate so that stringer/tabbers have limited throughput and are expensive.
The assembled solar cell circuit is very fragile prior to the lamination step.
The Cu ribbon interconnect must be narrow to avoid reflecting too much light, and can not be very thick or it becomes too stiff and stresses the cell. The net result is that the conductivity of the Cu interconnect is limited and the electrical losses due to the interconnect are large.
The above limitations make this process difficult to use with thin crystalline-silicon solar cells. Use of thinner Si reduces the cost of the solar cell.
The spacing between solar cells must be large enough to accommodate stress relief for the Cu interconnect wire, which reduces the module efficiency due to the non-utilized space between solar cells.
The process comprises many steps, thus increasing the manufacturing cost.

Back-contact solar cells have both the negative- and positive-polarity contacts on the back surface. Location of both polarity contacts on the same surface simplifies the electrical interconnection of the solar cells. It also enables new assembly approaches and new module designs. “Monolithic module assembly”, or “MMA”, disclosed in U.S. Pat. Nos. 5,951,786 and 5,972,732, which are incorporated herein by reference, refers to assembly of the solar cell electrical circuit and the laminate in the same step. Typical monolithic module assembly starts with a backsheet with a patterned electrical conductor layer. Production of such patterned conductor layers on flexible large-area substrates is well known from the printed-circuit board and flexible-circuit industries. The back-contact cells are placed on this backsheet with a pick-and-place tool. Such tools are well known and are very accurate with high throughput. The solar cells make electrical connection to the patterned electrical conductors on the back sheet during the lamination step; the laminated package and electrical circuit are thus produced in a single step and with simple automation. The backsheet includes materials like solders or conductive adhesives (electrical connection material) that form the electrical connection during the lamination temperature-pressure cycle. The backsheet and/or cells could optionally include an electrical insulator layer to prevent shorting of the electrical conductors on the backsheet with the conductors on the solar cell. A polymer layer can also be provided between the backsheet and the solar cell for the encapsulation. This layer provides low-stress adhesion of the backsheet to the solar cell. Open channels can be provided in this encapsulation layer where the electrical connection is made between the solar cells and the conductor layer.

The advantages of monolithic module assembly include the following:
Single-step assembly reduces the number of steps and reduces manufacturing cost.
The planar geometry is easier to automate and reduces the cost and improves the throughput of the production tools.
The Cu busses at the end of the modules can be reduced or eliminated, which reduces module size for reduced cost and improved efficiency.
The number and location of the contact points can be easily optimized since the geometry is only limited by the patterning technology. This is unlike stringer/tabbers where additional Cu interconnect straps or contacting points increase cost. The net result is that the cell and interconnect geometry can be more easily optimized with monolithic module assembly for improved cell and module cost and performance.
The geometry is much more planar compared to present practice, and thereby introduces less stress. Therefore, thin Si solar cells can be more easily used.
The electrical circuit on the backsheet can cover nearly the entire surface. The conductivity of the electrical interconnects can thus be very large because the interconnect is much wider. Meanwhile, the wider conductor can be made thinner (typically less than 100 μm) and still have low resistance. The thin conductor is typically more flexible than Cu ribbon interconnects, thereby reducing stress.
The spacing between solar cells can be made small since no stress relief of thick Cu interconnects needs to be maintained. This improves the module efficiency and reduces the module material cost (less glass, polymer, and backsheet are required due to the reduced unused area).

Monolithic assembly of 36-cell modules using 156×156-mm cells in a 4×9 array using conductive adhesives has been described by P. C. deJong, “Single-step Laminated Full-size PV Modules Made with Back-contacted mc-Si Cells and Conductive Adhesives,” 19^{th} Eur. PV Solar Energy Conference, Paris, FRANCE (2004), which is incorporated herein by reference. The electrical circuit on the backsheet is brought to a single point so that a single junction box could be used.

This invention describes approaches for implementing monolithic module assembly on larger photovoltaic modules with improvements for low-cost manufacturing. Larger modules are preferred by customers and have a lower production cost.

### BRIEF SUMMARY OF THE INVENTION

The present invention is a photovoltaic module comprising a plurality of back-contact solar cells, a flexible backsheet, a patterned metallization on the backsheet, an insulating material disposed between the patterned metallization and the solar cells, the insulating material patterned so as to enable electrical contact between the patterned metallization and the solar cells in desired locations, and a plurality of busses in electrical contact with the patterned metallization. The module preferably further comprises a moisture barrier on the backsheet, the moisture barrier being sufficiently thin to enable roll-to-roll processing of the backsheet combined with the patterned metallization and the moisture barrier. The insulating material preferably comprises an interlayer dielectric (ILD) preferably comprising islands or dots. At least a portion of the ILD preferably has been modified to change its appearance. The photovoltaic module preferably further comprises an encapsulant, which preferably comprises a thermoplastic material. The encapsulant preferably comprises a scrim layer disposed between the solar cells and the patterned metallization. The insulating material optionally comprises the encapsulant. The encapsulant is optionally integrated with the backsheet prior to assembly of the module, optionally laminated together using roll-to-roll processing techniques. The limited electrical contact is preferably provided by a material comprising a polymer matrix and conductive particles. The backsheet preferably comprises one or more openings through which the busses are extended. At least a portion of one or more the busses are preferably integrated with a trim strip prior to assembly of the module.

The present invention is also a photovoltaic module comprising a plurality of back-contact solar cells, a first insulating backsheet, a first patterned metallization in contact with a first face of the first insulating backsheet, a second patterned metallization in contact with a second face of the first insulating backsheet, an insulating material disposed between the first patterned metallization and the solar cells, the insulating material patterned so as to enable electrical contact between the first patterned metallization and the solar cells in desired locations, and a second backsheet in contact with the second patterned metallization. The second backsheet preferably comprises openings for the second patterned metallization to make electrical contacts external to the second backsheet. A portion of the first patterned metallization and a portion of the second patterned metallization preferably comprise different areas of a foil wrapped around an edge of the first insulating backsheet. A portion of the first patterned metallization and a portion of the second patterned metallization are preferably connected through at least one opening in the first insulating backsheet. The photovoltaic module optionally further comprises a plurality of flat pack bypass diodes. The photovoltaic module preferably further comprises a moisture barrier on the second backsheet, the moisture barrier being sufficiently thin to enable roll-to-roll processing of the backsheet combined with the second patterned metallization and the moisture barrier. The insulating material preferably comprises an interlayer dielectric (ILD), which preferably comprises islands or dots. At least a portion of the ILD has optionally been modified to change its appearance. The photovoltaic module preferably further comprises an encapsulant, which preferably comprises a thermoplastic material. The encapsulant preferably comprises a scrim layer disposed between the solar cells and the patterned metallization. The insulating material optionally comprises the encapsulant. The encapsulant is optionally integrated with at least one of the backsheets prior to assembly of the module, optionally being laminated using roll-to-roll processing techniques. The limited electrical contact is optionally provided by a material comprising a polymer matrix and conductive particles.

The present invention is also a photovoltaic module comprising a plurality of back-contact solar cells, a flexible backsheet, a patterned metallization on the backsheet, and a plurality of islands comprising an ILD material disposed between the patterned metallization and the solar cells. The photovoltaic module preferably further comprises a plurality of annuli comprising the ILD material, each annulus surrounding and containing a conducting material electrically connecting the solar cells and the patterned metallization. The conducting material optionally comprises a polymer matrix and conducting particles.

The present invention is also a backsheet assembly for a photovoltaic module, the backsheet assembly comprising a flexible backsheet a patterned metallization, and a moisture barrier sufficiently thin to enable roll-to-roll processing of the backsheet together with the second patterned metallization and the moisture barrier. The moisture barrier preferably has a thickness of less than approximately 25 μm, more preferably less than approximately 15 μm, more preferably less than approximately 10 μm, and even more preferably approximately 9 μm. The backsheet assembly preferably further comprises an ILD or an encapsulant laminated to the flexible backsheet or the patterned metallization.

The present invention is also a photovoltaic module comprising a plurality of back-contact solar cells, a flexible backsheet, a patterned metallization on the backsheet forming a plurality of circuits, each circuit connecting a subset of the solar cells, wherein at least one of the circuits comprises a non-linear circuit path, and a plurality of cord plates in multiple locations on the module, each cord plate electrically comprising one or more bypass diodes for bypassing one or more of the circuits. The solar cells optionally comprise upgraded metallurgical grade silicon or low-resistivity silicon. Each bypass diode bypasses less than 20 solar cells, and more preferably less than 16 solar cells, and more preferably less than 11 solar cells, and more preferably less than 7 solar cells.

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWINGS

The accompanying drawings, which are incorporated into and form a part of the specification, illustrate several embodiments of the present invention and, together with a description, serve to explain the principles of the invention. The drawings are only for the purpose of illustrating one or more particular embodiments of the invention and are not to be construed as limiting the invention.

FIG. 1A is a plan view of an embodiment of the MMA module of the present invention comprising a busbar.

FIG. 1B is a cross-section view of the embodiment of FIG. 1A.

FIGS. 1C and 1D show the embodiment of FIG. 1A with added details.

FIG. 2 is an exploded view of the embodiment of the MMA module of FIG. 1.

FIG. 3 is a cutaway view of the embodiment of the MMA module of FIG. 1.

FIG. 4 is a cross-section view of a first multi-level metallization embodiment of the present invention.

FIG. 5 is a cross-section view of a second multi-level metallization embodiment of the present invention comprising a double-sided flexible circuit.

FIGS. 6 and 7 are two alternative embodiments showing possible interconnect layouts for MMA modules.

FIG. 8A shows a prior art module comprising a single junction box.

FIG. 8B shows a module comprising multiple cord plates, each comprising a bypass diode, distributed across the module.

FIG. 9 shows flat pack diodes useful for multilevel metallization embodiments of the present invention.

FIG. 10 shows a back sheet overlayed with a patterned metallization.

FIG. 11 shows the metallized backsheet of FIG. 10 overlayed with an interlayer dielectric (ILD) sheet comprising vias.

FIG. 12 is a cross-section view of FIG. 11 or FIG. 13.

FIG. 13 shows ILD dots or islands disposed on the metalized backsheet of FIG. 10.

### DETAILED DESCRIPTION OF THE INVENTION

### Monolithically Integrated Cu Bussing

As used throughout the specification and claims, the term “bus” means a bus bar, bus ribbon, bus strap, or any other conductive element suitable for current bussing.

In photovoltaic modules using conventional cells, the solar cell strings are terminated at the top and bottom of the module using copper (Cu) bus straps. These Cu bus straps are often coated with Sn or Sn/Ag to prevent interaction with the encapsulant and to enhance solderability. The current needs to be transported a long distance (up to half the width of the photovoltaic module) to the junction box in the center of the module. The Cu bus straps need a large cross sectional area to have sufficiently low resistance to transport current such a long distance with low resistance losses.

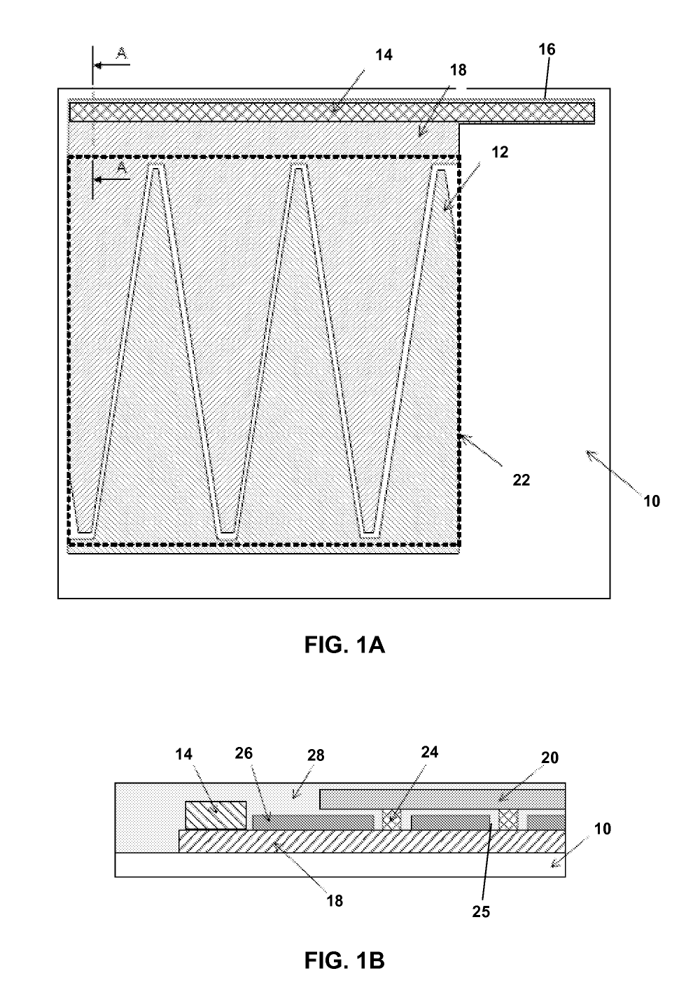

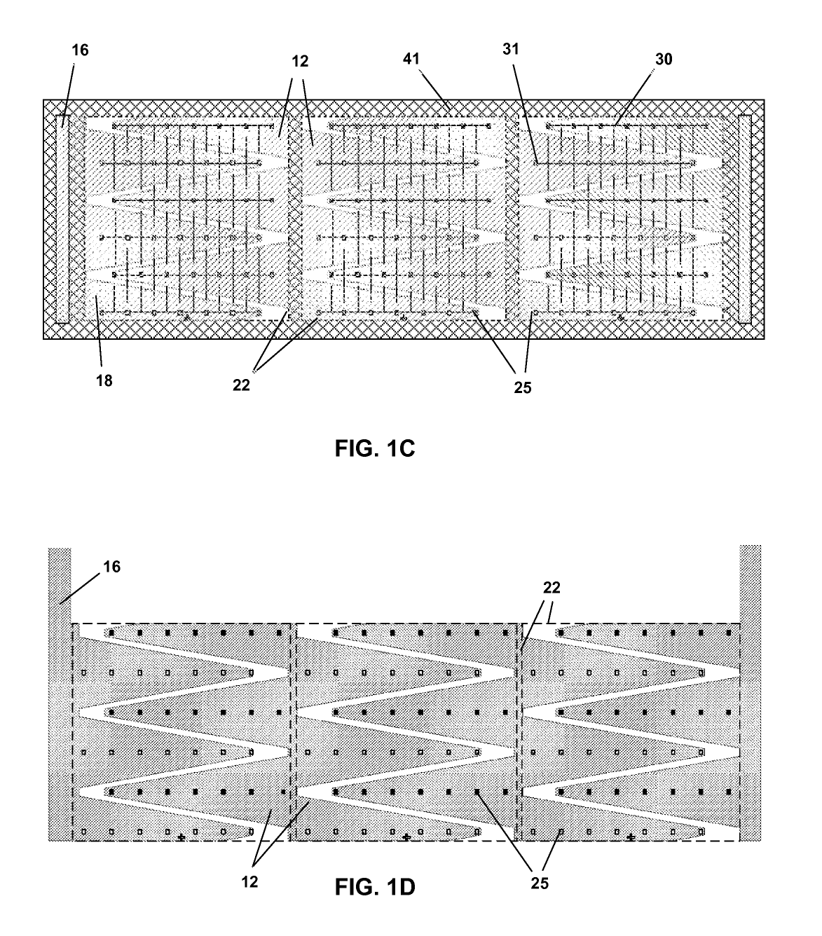

In monolithic module assembly, shown in FIGS. 1A-1D, the solar cells are preferably interconnected using thin metal metallizations or foils 12, 18 of opposite polarity (preferably comprising copper) patterned into an electrical circuit on backsheet 10. Cells 20 are preferably electrically connected to patterned foils 12, 18 via conductive adhesive 24, which extends through vias 25 in interlayer dielectric (ILD) 26. The ILD provides electrical isolation between the solar cells and the metal foils. The module is preferably encapsulated in encapsulant 28. The outlines 22 of solar cells 20 are shown, as are the positions of first polarity gridlines (or metallizations) 30 and opposite polarity gridlines (or metallizations) 31 on the back surfaces of the solar cells.

The electrical resistance losses in the patterned metallizations are typically unacceptably high unless a very wide foil conductor is used needed to carry the current the long distance to a junction box. To avoid the need for large areas of foil or other metal, a bus strap or bus bar 14 is preferably overlaid on a narrow strip of metal foil 16 to obtain the necessary cross sectional area while reducing the foot print of the interconnect. The electrical power loss in the bus is preferably minimized with the increased cross sectional area while loss in module efficiency is preferably minimized by minimizing the footprint of the bus. The bus ribbon also provides a convenient means connecting the cell strings to the junction box through an opening in the back sheet.

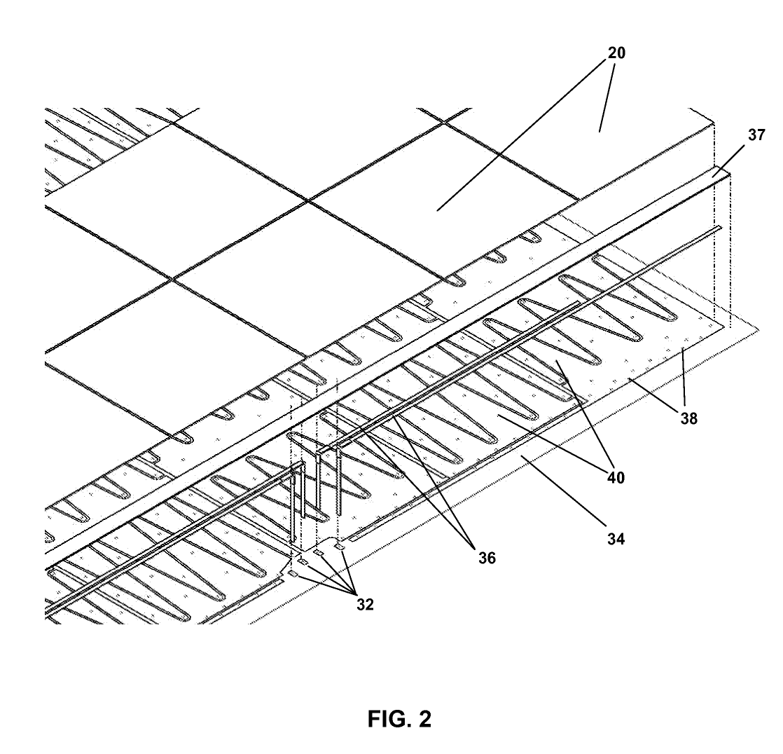

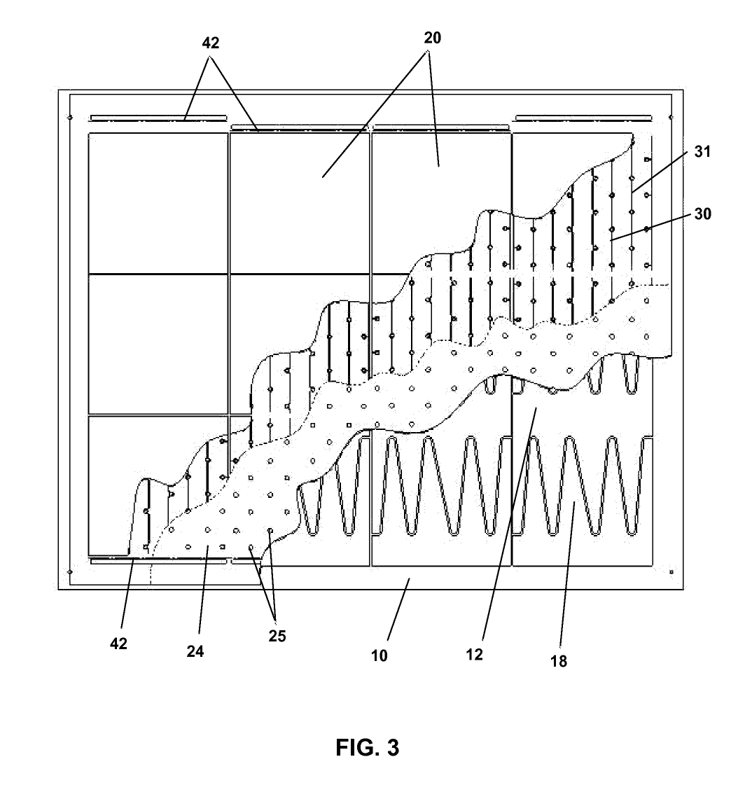

FIG. 2 shows the entire module package with an integrated copper bus bar. In this embodiment, one or more openings 32 are provided in the backsheet 34 (comprising patterned metallization) where bus ribbons 36 are bought to the exterior of the module laminate for connection to the junction box. The Cu busses can either be preassembled on the backsheet, or they could be inserted via a pick-and-place robot during monolithic module assembly and adhered to the metalized backsheet via conductive adhesive 38. Photovoltaic cells 20 are preferably applied via pick and place and attached via conductive adhesive 40 to the patterned metallization.

For aesthetic purposes, many PV module manufacturers opt to place a ‘trim strip’, or cover layer over the ribbon bussing to hide unsightly solder joints and ribbon. Trim strips typically comprise pigmented PET or other inert polymer or fabric. Trim strip 37 may be placed over the Cu busses in MMA assembly. The Cu buses may alternatively be cut to length and attached to a trim strip as a wholly integrated sub assembly. The ribbon may be attached with a compatible adhesive or through a thermoset process. This sub assembly would reduce the bussing portion of the MMA process to a simple pick and place operation of two subassemblies versus seven (or more depending on module size) individual bus ribbons—thereby reducing piece count and assembly complexity. Such an assembly could be ordered from a variety of commercial vendors as a component. In addition, it may also be advantageous to mount bypass diodes or a variety of other ICs and circuitry on the subassembly for functions such as shade protection, module troubleshooting & monitoring, RFID tracking, etc. The trim strip may have its own etched conductive traces similar to the MMA backsheet to create complete circuits, isolated from the backsheet. Alternatively, the ILD may comprise materials to change its physical appearance, such as pigmentation, to change the appearance of the module. This pigmented ILD is only necessary to be printed in regions that are visible from the front of the module. An example of this is shown in FIG. 1C, where pigmented ILD 41 forms a “picture frame” around the solar cells, and optionally bus ribbons, to provide a more pleasing appearance.

The bus bar(s) or bus bar assembly is preferably laminated during module assembly. FIG. 3 shows a plan view of the module construction with layers cut away for clarity of viewing the construction. Edge locations 42 for the bus ribbons are shown.

### Multi-Level Metallization

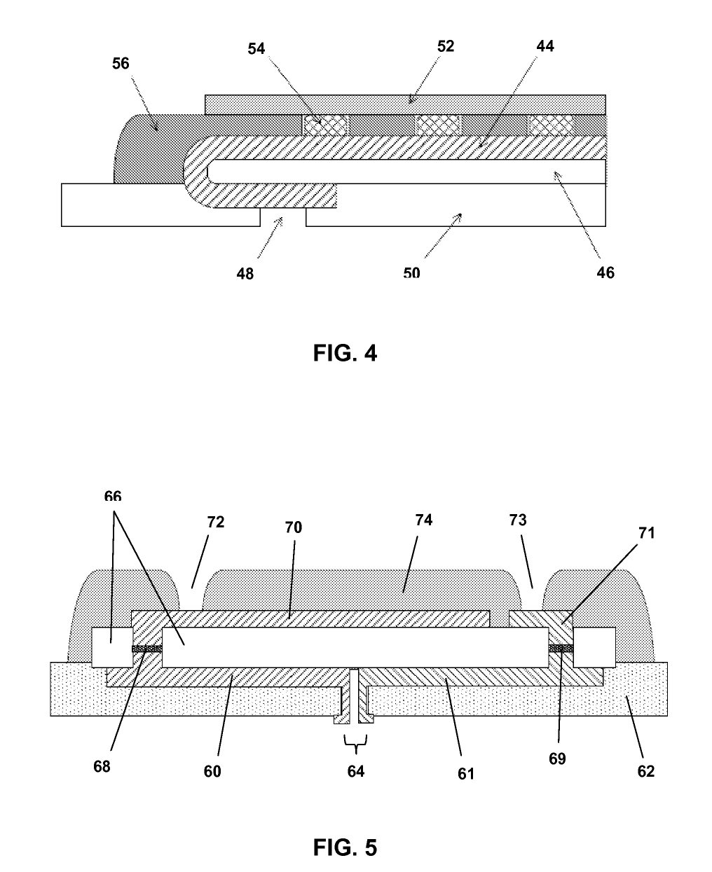

The bus function can be accomplished without bus bars, and thus without an increase in area, through the use of a multi-level metallization on the backsheet, as shown in FIG. 4. Multilevel metallization refers to two or more layers of metallic conductors separated with an electrical insulator(s). The layers may be interconnected at various points through conductive vias in the electrical insulator. Multi-level metallization allows one level to contact cell and transport current to adjacent solar cells in the circuit, while the second level is used to transport current to the junction box or provide other functions. Hence, additional area for the bus is not required. In this embodiment single level conductive foil 44 wraps around the ends of inner back sheet 46, thereby forming a multilevel metallization, and preferably conducts the current to the junction box out through opening 48 in outer back sheet 50. Foil 44 is in electrical contact with solar cell 52 via conductive material 54 which is disposed in openings in ILD (and/or encapsulant) 56.

Several processes could be considered for producing the multilevel metallizations for the patterned conductor on the backsheet. In one embodiment, the first conductor, insulator, and second conductor are subsequently applied and patterned on the substrate. Additional conductor and insulator layers could be built up with the same manner. The application could be by deposition, by lamination of metal foils and dielectric films, or by other means. In this embodiment, the substrate for the conductor and insulator layers can include materials suitable for use as the external backsheet for the photovoltaic module.

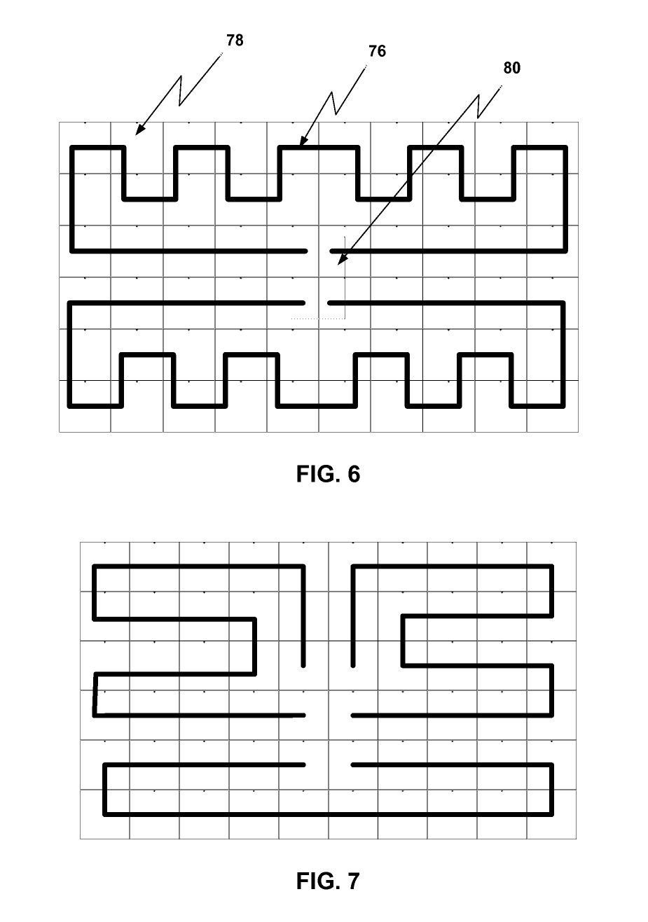

In a second embodiment, the conductor layers are applied on opposite surfaces of a substrate. Such structures are known as “double-sided flexible circuits.” The substrate may include conductive vias through the substrate for electrical connection between the conductors on the opposite surfaces. Since a double-sided flexible circuit has electrical conductors on both surfaces, an additional encapsulant and backsheet must be laminated over the flexible circuit to provide the necessary environmental protection to the solar cell circuit. A cross section of a double-sided flexible-circuit for a photovoltaic module is illustrated in FIG. 5. First metal foil layers 60, 61 extend through opening 64 in outer backsheet 62 in order to interface with an external connection. Foil layers 60, 61 are preferably of opposite polarity. First metal foil layers 60, 61 at least partially extend through openings in inner insulating backsheet 66 where they respectively connect via bonds 68, 69 to second metal foils 70, 71. Second metal foils 70, 71 connect to the solar cells (not shown) through vias 72, 73 respectively in ILD 74.

### Serpentine Cell Layout

The circuit layout on the backsheet can be quite flexible since it is only limited by the patterning technology. This is unlike conventional photovoltaic modules with Cu ribbon interconnects where the solar cells must be in a straight line due to the flat Cu ribbon interconnect. The circuit layout in the monolithic backsheet can also be designed so that the cells in electrical series are not in a straight line; i.e., the circuit can make right-angle turns. These circuits are thus non-linear. The latter capability allows for non-linear geometric layouts of the solar cell circuit that do not require busses at either end of the module, which increases module efficiency and reduces cost. Two such designs, showing interconnect or current flow paths 76 as dark lines, are illustrated in FIGS. 6 and 7 for a module comprising 60 solar cells 78 in a 6 column by 10 row array. These designs comprise multiple strings that terminate at a central location, e.g. junction box opening 80, thereby requiring only a single junction box. Ultimately, this design reduces costs of the module by allowing for a simpler junction box and cable layout. In addition, by keeping series and parallel connections beneath the cell, less encapsulant, glass, frames, and backsheet material are required.

### Multiple Junction Boxes and Cord Plates

A common approach is to place the junction box towards the top and center of the module. This placement requires highly conductive busses, as previously described, to bus the current to the junction box. The placement and interconnection of the junction box is described relative to using a Cu ribbon bus. In this approach, a typical copper bus ribbon, such as that used to interconnect conventional solar cells, is preferably bonded to the metal foil at the top and bottom of the monolithic backsheet of the module. To pass the ribbon into the junction box, the back sheet is preferably die cut to remove material and provide an opening into the rear of the junction box. It may also be feasible to bring the ribbon through the backsheet into the junction box using slits.

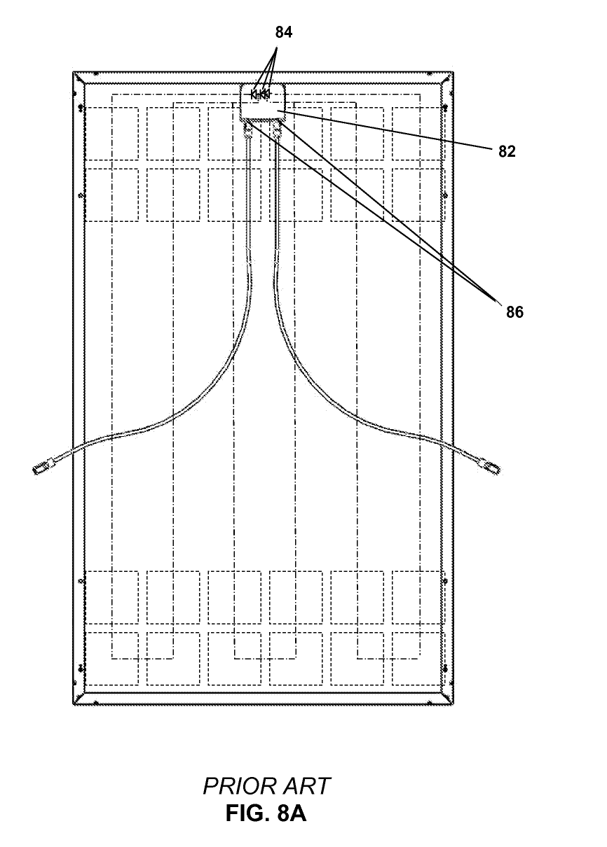

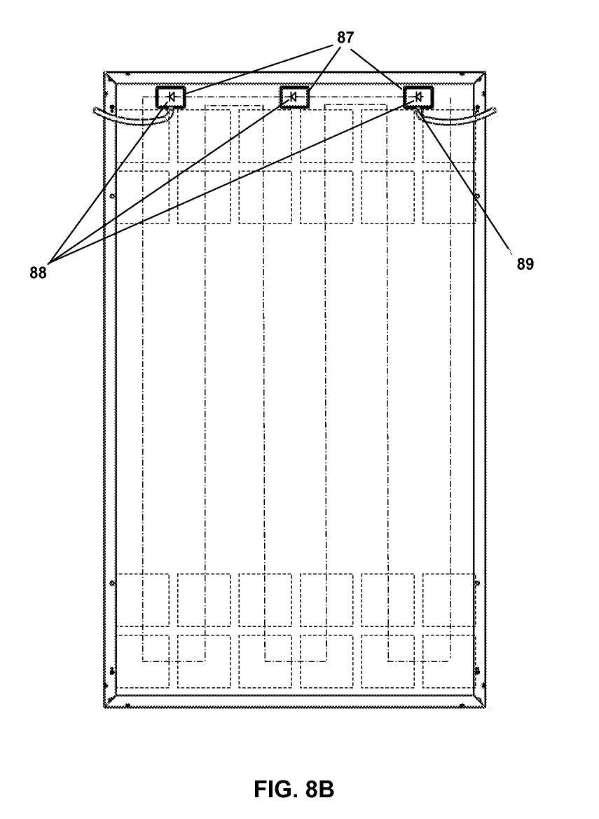

As shown in FIG. 8A, when only a single junction box 82 is used for a module, the junction box needs to be relatively large to house both multiple bypass diodes 84 (one for each cell string) and the two cable connections 86. As shown in FIG. 8B, several smaller “junction boxes” may alternatively be used rather than using a single large junction box. Each such junction box 87 can be smaller since it preferably houses only a single bypass diode 88 and optionally only a single cable connection 89. The smaller junction boxes are preferably located near the location of the bypass diodes in the circuit or solar cell circuit termination, so the length of the busses to bring current into the smaller junction boxes is greatly reduced. The multiple junction boxes require a larger number of penetrations of the backsheet to bring out the electrical leads. Such small junction boxes are sometimes called “cord plates” since they have a flat profile with a cable. A convenient format provides the multiple cord plates in a single injection-molded enclosure so that fewer parts are handled during the assembly.

The use of multiple cord plates has several advantages for monolithic module assembly. The multiple cord plate approach reduces the length of the internal buses, which works particularly well with monolithic module assembly since it can reduce or even eliminate the need for additional internal buses. The geometry of the circuit layout can be more varied with use of multiple cord plates, as is described above. The cord plate themselves are often less expensive compared to a large junction box, although they do require more penetrations of the backsheet for the electrical connection to the solar cell circuit.

For assembly of a multiple cord plate with a monolithic backsheet, the conductor (e.g. foil) layer in the backsheet is preferably exposed at the mounting location. A typical 60-cell module is arranged in a 6×10 array (6 columns of 10 rows) and has 3 bypass diodes. For this design, cord plates are preferably mounted in three different locations above the top row of cells, as shown in FIG. 8B. A bypass diode is preferably included in each cord plate. The cord plates connected on opposite edges of the module are also at the two ends of the solar cell circuit. These cord plates will also be connected to a cable, in addition to the diode, which will correspond to the positive and the negative connector for the module. For a 6×10 array of cells, typically 3 boxes are used, (left, center, and right), each preferably comprising at least one bypass diode.

A larger number or different geometric arrangement of the cord plates can be used to accommodate different circuit layouts for the solar cells or different number of bypass diodes. For example, the solar cell circuit can use a non-linear serpentine layout where all the strings terminate near a single point, as shown in FIG. 7. In this configuration the cells are connected in a serpentine pattern in which all strings preferably terminate near the center of the module. The cord plate preferably spans across as many three cells in order to access all the strings. Within the junction box string interconnections will be made as well as interconnection to diodes between each string end. In this configuration no additional bussing ribbon is necessary, the backsheet will not need to incorporate special bussing channels to the center, and there is preferably an increase in module efficiency.

The serpentine circuit may alternatively be designed in conjunction with multiple cord plates to terminate at multiple points. In this embodiment the serpentine circuit may comprise additional bypass diodes. A conventional module has long linear strings of solar cells across the length of the module. The only convenient location to insert a bypass diode is at the end of the module, so that there are typically a large number of cells in series per each bypass diode—e.g., 20 cells per bypass diode for a typical module with 60 cells arranged in 6 strings of 10 cells each. The solar cells must have a reverse breakdown voltage greater than the sum of voltages in a string, and the output of the entire string is potentially lost if one cell in the string is shaded. In this embodiment of the present invention, the serpentine circuit can have much shorter strings (i.e. fewer cells) per bypass diode by including a cord plate with bypass diode across each string in multiple locations on the module. For example, the circuit may optionally be designed so that a bypass diode is used across every 6 cells. This enables the use of solar cells manufactured from low cost low-resistivity Si (e.g. upgraded metallurgical grade silicon) that tends to have low reverse breakdown voltages. In addition, energy production is improved because less power is lost when a single cell is shaded; only the power of the shorter string is lost. It is preferable that there are less than 20 solar cells per bypass diode, and more preferably less than 16 solar cells per bypass diode, and more preferably less than 11 solar cells per bypass diode, and more preferably less than 7 solar cells per bypass diode.

### Flat Pack Diode Integration

A typical photovoltaic module is constructed by stacking several layers of different materials and sealing them together in a lamination process. A typical photovoltaic module laminate lay-up begins with a sheet of glass. On the sheet of glass a sheet of ethylene vinyl acetate (EVA) is laid. EVA is a soft thermal setting transparent polymer. A variety of other materials could be used for the encapsulant other than EVA. On top of the EVA a series of cell strings are laid out. Generally each string consists of a series of solar cells interconnected in series. Once the cells are laid on the EVA, bussing tabbing is bonded to the beginning and ending cells of each string interconnecting the individual strings. This bussing is generally constructed from individual pieces of metal ribbon, typically comprising Sn or Sn/Ag coated Cu. After the interconnecting is complete, another sheet of EVA is laid on top of the strings extending to the limits of the glass. Finally a sheet of backing material is laid on top of the EVA, also extending to or beyond the extents of the glass. During the layup of the second sheet of EVA back sheet penetration will be made to bring out the ribbons for external contacting.

Typically a module will consist of several strings in series. A “bypass” diode is placed between each string electrically in parallel with the string of solar cells. The purpose for the diode is to allow current from other strings and the external circuit to bypass the string when the string is not conducting, as in the case of shadowing. These diodes are typically mounted within a junction box. These diodes are typically discrete packaged devices, typically of the axial package type. Typically each string is protected by a single diode large enough to safely conduct the full current of the string and withstand in reverse bias the full voltage generated by the string of solar cells.

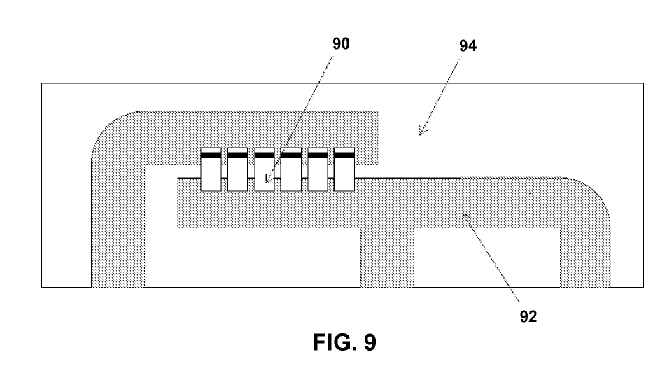

Diodes with a flat profile can potentially be directly assembled on the flexible circuit in monolithic module assembly. In one embodiment shown in FIG. 9, flat pack diodes 90 are preferably incorporated into the flex circuit used to protect the cell strings comprising metal foil 92. A plurality of flat pack diodes that have a combined current capacity as large as or greater than the string current is preferably used, which helps distribute the thermal load over a larger area. The flat-pack diodes can be placed onto backsheet 94 and assembled in the module during the monolithic module assembly process. Alternatively, the diodes can be bare semiconductor die that are attached to the flexible circuit in a manner similar to the solar cells in MMA assembly. Or, as previously described, the flat-pack diodes could be integrated on a subassembly containing the bus ribbons.

### Electrical Isolation of the Flexible Circuit and Solar Cell

The electrical circuit on the rear surface and the conductors on the solar cell must the electrically isolated to prevent shorts. The encapsulant layer between the cell and the backsheet circuit typically has sufficient dielectric strength to serve this function. However, its thickness may be very non-uniform because the vacuum/pressure lamination step can produce very thin regions. In addition, the application of the electrical attachment material or placement of the solar cell may be imprecise. The use of electrical insulator layers on either the solar cell or on the flexible circuit to provide greater tolerances in the assembly while reducing the possibility of electrical shorts has been previously described.

The MMA backsheet is typically constructed using techniques developed by the flexible circuit industry. A metal foil, typically copper, is bonded to a carrier material. The most common carrier materials are Kapton and polyester. The circuit is then patterned using etching resists which are patterned either photolithographically or directly by screen printing. The excess metal foil is then typically removed by an etching process. The final step in the process is to apply a protective layer over the metal foil using a solder mask or cover lay. They are applied using patterns that cover the metal everywhere by where it is desired to make contact with the metal. These materials may alternatively be applied by means of screen printing.

The present invention preferably utilizes a MMA backsheet which comprises a copper metal foil bonded to a thin insulative carrier material and patterned in such a way as to allow for the series interconnection of back contact solar cells. The metal foil is preferably coated with a material, preferably with a polymeric material, that acts as an insulator to prevent the cell from contact the foil at undesired locations. This coating is referred to as the ILD, or interlayer dielectric. The ILD is typically applied by screen printing and is patterned such that vias are formed where the cells are to be bonded to the metal foil.

Typically the ILD layer is printed as a continuous sheet covering the metal foil and surrounding carrier materials everywhere but where openings are required to contact the solar cells. These opening are generally several millimeters in diameter and correspond directly to the contact points on the solar cells.

During assembly, sealing the ILD over the entire backsheet inherently produces large shear stresses between the metal foil and ILD due to a mismatch in their coefficients of thermal expansion (CTE). This mismatch causes the bond between the ILD and metal foil to fail over time and eventually separate. This failure mechanism is manifested rapidly when modules constructed with an MMA backsheet are subjected to thermal cycling testing (typically the temperature of the module is cycled between −40° C. and 85° C.) or damp-heat testing (typically 85° C. and 85% relative humidity).

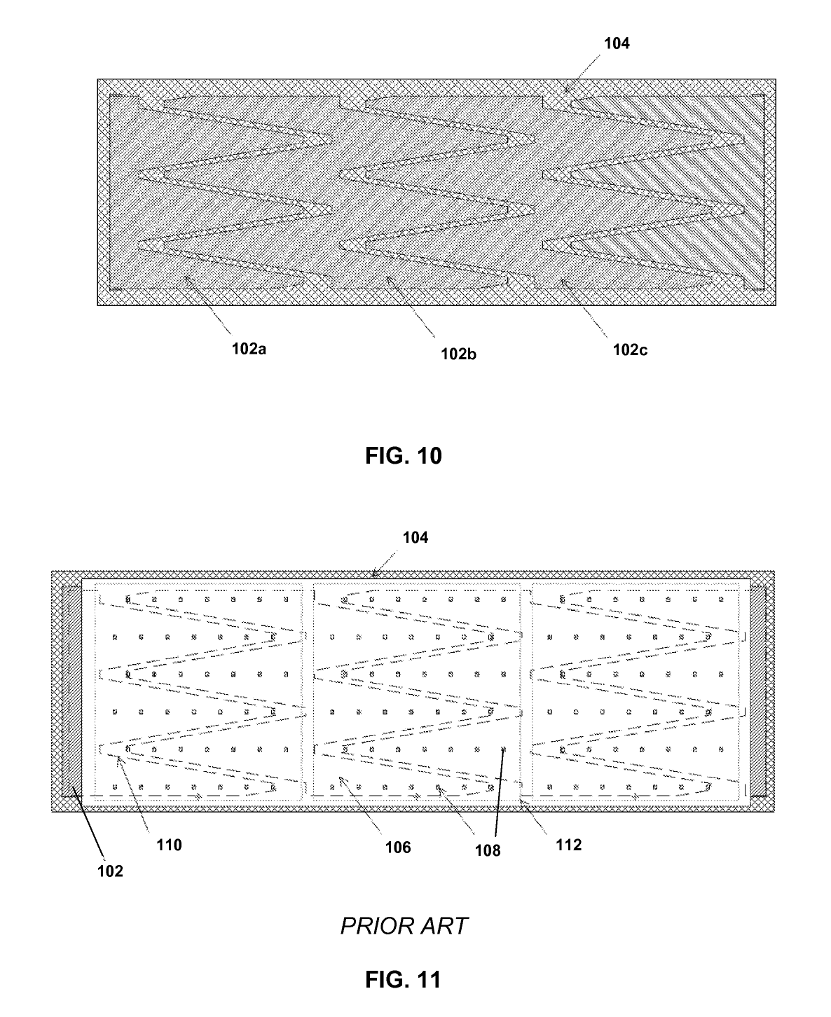

FIG. 10 illustrates metal foils 102a, 102b, 102c patterned on carrier film 104. Typically the carrier foil preferably comprises a 100 to 250 μm foil of polyester (for example, PET or Mylar), although the foil could comprise any appropriate insulator that is flexible and can be bonded to the metal, such as Kapton or PVFE. The metal foil preferably comprises a 35 micron soft copper foil, although any metal or alloy can be employed, optionally comprising a coating finish such as silver, tin or organic soldering preservative (OSP). Such a finish coating is preferably very thin (typically less than about 1000 nm).

FIG. 11 illustrates a typical module with a continuous ILD sheet 106 printed over the metal foil and comprising via openings 108 where the cells contact the underlying foil. Also shown are outlines 110 of the underlying metal foils and outlines 112 of the solar cells as they would be placed over the ILD.

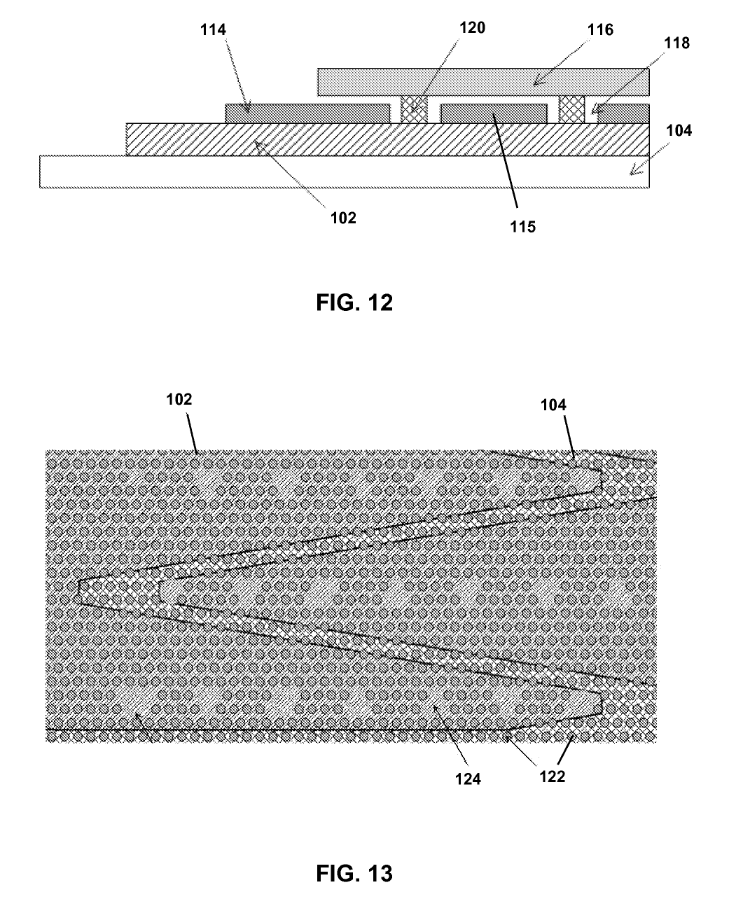

FIG. 12 illustrates the assembly in cross section. Patterned metal foil 102 is disposed on carrier film 104. ILD 114, 115 is disposed between metal foil 102 and solar cell 116. Openings 118 in the ILD accommodate conductive adhesive 120, which electrically connects solar cell 116 to metal foil 102. ILD 114, 115 thus confines conductive adhesive 120 to the openings 118. In the embodiment shown in FIG. 11, openings 118 correspond to vias 108 and ILD 114, 115 comprises a continuous sheet.

Accordingly, if the surface area of the ILD in contact with the metal foil is reduced then the shear stresses between the ILD and metal will also be reduced, and the ILD will not readily delaminate from the metal foil. To achieve this reduction in area of the continuous ILD layer, the ILD preferably comprises discrete islands, thereby reducing the area of each discrete island in contact with the metal foil. This patterning is referred to as the dot matrix ILD layer. FIG. 13 illustrates the ILD printed as dots or islands 122 over carrier film 104 and metal foils 102. The ILD is preferably not printed within the areas where the EWT cells are to be bonded to the underlying metal foil (bond pad areas 124), similar to vias 108 in a continuous ILD sheet. Thus the ILD dots are preferably arranged around each bond pad area (in any shape), leaving sufficient blank area to accommodate the conductive adhesive and preventing it from spreading out too far and shunting the cell. Thus the ILD confines the conductive adhesive to the bond pad openings. In accordance with this embodiment, in FIG. 12 openings 118 correspond to bond pad areas 124, and ILD 114, 115 comprises discrete dots or islands upon which solar cell 116 rests. Annuli comprised of ILD are preferably disposed around the each of the bond pad areas (within the innermost dots) to create a well to confine the conductive adhesive that is used to connect the cells to the metal film from spreading when the cells and back sheet are mated.

The dot matrix pattern is preferably designed such that at least a portion of each edge of each solar cell always falls on top of a pillar of ILD regardless of alignment and rotation on the backsheet. The placement and rotation are preferably limited to displacements that still provide good contact between the EWT cell and the backsheet. Each discrete island is preferably at least 1 mm² in area, although the size of the ILD islands can be varied over the backsheet as desired. The thickness of the ILD is preferably similar to the thickness when printed as a continuous film. The ILD material may optionally comprise a solder mask of flexible cover lay which can be UV or thermally cured.

In another embodiment, the electrical isolation layer (ILD) is disposed on the cell in addition to, or instead of, the flexible circuit. The ILD can be applied by screen printing or related techniques, and can use similar materials to the ILD used for flexible circuits. The advantage for this placement is that the print step on the smaller cell can be more accurate than that on a large flexible circuit. Also, it can be placed only over the areas requiring electrical isolation (e.g., grid lines with opposite polarity compared to the adjacent circuit layer), and it avoids the stresses associated with ILD on the very large backsheet.

In another embodiment for providing electrical isolation, a scrim material can be used in the encapsulation layer. “Scrim” refers to a discrete sheet of fiberglass or related material. The scrim is frequently porous mesh so that the encapsulant material can flow through the scrim and bond to the cell and to the backsheet. The scrim can be provided as a separate layer or pre-integrated with the encapsulant. The scrim reduces shifting of cells during lamination and prevents the encapsulant from becoming too thin during the vacuum/pressure lamination—thereby preventing electrical shorts between the cell and the flexible-circuit backsheet.

### Thermoplastic Encapsulant

Typical photovoltaic modules are constructed using a successive layup process. The process begins with a sheet of glass, which will be come the front of the module. With the glass face down on a horizontal surface a sheet of encapsulant, typically EVA is placed on the glass. On top of the EVA a series of cell strings are placed and their interconnects at the beginning and end of the strings are soldered together. Another sheet of EVA is then placed over the cells followed by a backsheet, typically a Tedlar/Polyester foil with the polyester facing the cells. The entire package is then placed in a press laminator to bond the package together.

The MMA module assembly process is very different. It begins with a backsheet into which the electrical circuit or cell interconnects have been incorporated and may or may not be covered with an inter layer dielectric (ILD); this assembly is the integrated or MMA backsheet. A sheet of encapsulant may be placed over the integrated backsheet before the cells are placed thereon. The sheet preferably comprises openings, preferably punched out, corresponding to the vias or bond pad openings where the cells are to be interconnected to the backsheet through the application of a conducting material such as a conductive adhesive. The conductive adhesive is preferably applied to the backsheet through the use of a stencil. Once the cells are in place on the encapsulant layer, another layer of encapsulant is preferably laid over the cells, and finally a cover glass is laid over the second layer of encapsulant. The entire package is then typically subjected to heat and pressure to bond the layers together.

Monolithic module assembly requires that the electrical connection material bond to the flexible circuit and to the solar cell during the lamination step. The time-pressure cycle of the lamination step is mostly determined by the properties of the encapsulant. The electrical connection material is most likely a conductive adhesive or a solder material with a low melting point to be compatible with typical lamination temperatures. The most common encapsulant for photovoltaic modules is a thermosetting polymer consisting of ethylene vinyl acetate (EVA). The EVA melts and flows during the thermosetting reaction, and releases various chemicals and gases during the curing reaction—which can all interfere with the ability of the electrical connection material to bond to the flexible circuit or solar cell. The EVA is also very soft (low elastic modulus) so that most of the stress is transmitted to the electrical connection material and bonds—which could degrade the reliability of the photovoltaic module. Finally, EVA has relatively poor adhesion to glass and other materials in the photovoltaic module. The adhesion is further degraded during damp heat exposure if the module uses a moisture-permeable backsheet.

In monolithic module assembly, the conductor layer in the backsheet covers most of the surface and is an excellent gas and moisture barrier. It is routine in high-volume production to only partially cure the EVA in order to maximize throughput of the lamination step and minimize production cost. The EVA would need to be cured completely during the lamination step when using moisture- or gas-impermeable packaging due to reliability concerns. The problem is that partially cured EVA will continue to cure and generate gas during use, and gas bubbles could accumulate in the package if the backsheet is gas impermeable.

Thermoplastic materials, such as ionomers, polyvinyl butyral (PVB), polyurethanes, ethylene copolymers, polyethylene, silicone, or similar materials have also been used as encapsulants in photovoltaic modules. Thermoplastic encapsulants provide the following advantages compared to the more common thermoset EVA encapsulant for modules assembled using monolithic module assembly.
Since there is no chemical reaction during lamination with thermoplastic materials, a thermoplastic encapsulant will provide a chemically more homogeneous environment that will interfere less with the bonding of the electrical connection material (such as a conductive adhesive) during the lamination step, which is unique to the MMA process of the present invention.
A thermoplastic polymer can have a wider process window so that a lamination process can be devised to be more compatible with the requirements of the electrical attachment material rather than just of the encapsulant.
Thermoplastic polymers can be much stiffer (higher elastic modulus) so that more of the stress in the package is accommodated in the encapsulant rather than at the critical electrical bond.
Thermoplastic encapsulants have excellent adhesion to glass and other interfaces in the photovoltaic laminate, which again helps reduce stress transmitted to the critical electrical bond and improves the reliability of the entire package.
Thermoplastic encapsulants are more compatible with moisture- and gas-impermeable backsheets due to the absence of chemical reactions and products.
Compared to EVA, thermoplastic encapsulants may be easier to integrate with the cell and/or the backsheet to simplify assembly. The thermoplastic may be brought above the melting point repeatedly without degrading the material, while a cured thermoset material will largely lose the ability to bond to other materials after the curing reaction is complete.

In another embodiment, the encapsulant can be included on or integrated with the MMA backsheet. This further simplifies the MMA assembly process by eliminating the step for patterning and laying out the encapsulant layer. The encapsulant can be laminated to the backsheet using roll-to-roll processing techniques. In an alternative embodiment, the encapsulant is integrated with the cells.

### Hybrid Adhesive/Solder for Photovoltaic Modules

Monolithic module assembly may utilize electrically conductive adhesives and/or solders for the electrical connection material. These materials must bond during the lamination step, which typically takes place at less than 200° C. peak temperature. Electrically conductive adhesives typically consist of a polymer matrix (epoxy, silicone, polyimide, acrylic, polyurethane, etc.) with conductive particles. The conductive particles typically comprise Ag. Electrically conductive adhesives may require special metal surface finishes (for example, Ag or Au plating) to avoid corrosion effects and promote good adhesion. The disadvantages of electrically conductive adhesives are the difficulty in bonding to surfaces, the cost of the special metal surface finish, the process window of the electrically conductive adhesive (finite lifetime after they are brought to room temperature), and degradation over time with heat and humidity. High-temperature solders are disadvantageous because the high required curing temperatures are incompatible with the polymers used for the encapsulant and for the backsheet. Low-temperature solders, like Sn:Bi or In-based alloys, are compatible with typical lamination temperatures, but are known to have difficulty wetting other metal surfaces easily and are frequently brittle.

A hybrid material that has properties of both an electrically conductive adhesive and a low-temperature solder consists of a polymer matrix with particles consisting of metal alloys with low melting points (i.e., low-temperature solder). The polymer matrix provides the adhesion and a soft durable matrix, while the melt and reflow of the low-temperature solder particles provides low interfacial resistance and a low bulk resistance.

Moisture Barrier Integration with MMA Backsheet

It is frequently advantageous to use a moisture-barrier layer in the backsheet. Moisture can cause corrosion and degrade materials or interfacial adhesion. Addition of a moisture barrier layer in the backsheet can significantly reduce and nearly eliminate moisture intrusion into the photovoltaic module, thereby eliminating moisture-related degradation modes. The glass on the front surface is an excellent moisture barrier, so moisture intrusion through the rear surface is typically more of a problem. The most common moisture-barrier materials used for the rear surface in photovoltaic modules include either glass (which results in a heavy module and is expensive) or Al foil. The Al foil is typically 25 to 50 μm thick. Thin-film dielectric films have also been used as moisture barriers. These films are typically deposited directly on a polymer sheet and integrated into the photovoltaic backsheet construction.

It can be advantageous to incorporate a moisture barrier in the backsheet in monolithic module assembly (MMA). The moisture barrier permits a wider number of metal surface finishes and electrically conductive materials to be considered, provides protection from corrosion and oxidation to the large area of Cu foil that is commonly used for the electrical circuit layer, and improves the reliability of the entire package.

The MMA backsheet consists of the flexible-circuit layer (substrate, metal circuit, and electrical insulator layers) and the outer layer for electrical and environmental protection. The outer environmental protection layer is typically a fluorinated polymer such as DuPont Tedlar on a relatively thick polyester layer for scratch tolerance and electrical isolation, although a variety of other materials have also been used. A moisture-barrier layer, e.g., 25 to 50 μm Al, can be included in the outer backsheet for improved environmental protection as previously described. The flexible-circuit is preferably bonded to the outer backsheet by a lamination process. The lamination is preferably roll-to-roll in atmosphere for low production cost.

This construction with Al foil in the outer backsheet is robust for environmental performance and high reliability, but it is not particularly manufacturable. Each MMA backsheet used in current modules must be assembled individually in a vacuum/press laminator to assemble the flexible-circuit layer to the outer layer. This process has low throughput and is more expensive than roll-to-roll lamination. Roll-to-roll processing typically is not available because the MMA backsheet with moisture barrier, including 35 to 50 μm Cu for the circuit and 25 to 50 μm Al for the moisture barrier, becomes too stiff for roll-to-roll processing.

To solve this problem, a more flexible MMA backsheet construction with moisture barrier is desired. In one embodiment, a flexible MMA backsheet uses a much thinner Al foil, the foil having a thickness of less than approximately 25 μm, more preferably less than approximately 15 μm, even more preferably less than approximately 10 μm, and most preferably approximately 9 μm. Thinner foils could be considered if they can be mechanically handled in the roll-to-roll lamination process. In this embodiment, the Al foil is bonded to the substrate used for the outer layer—such as 250 μm polyester (PET). A fluorinated polymer—such as DuPont Tedlar (PVF)—is bonded over the Al foil for environmental protection. The copper layer, preferably comprising a foil, can be bonded to the PET on the opposite surface using a roll to roll process. This helps to stiffen the PET to prevent tearing of the Al foil. Once the Cu foil is bonded to the PVF/AL/PET composite it can be processed using typical roll to roll techniques currently employed to form the circuit on the MMA backsheet. Alternatively, a thin-film moisture barrier can be used rather than thin Al foil for production of a MMA backsheet with improved processing capability.

Although the invention has been described in detail with particular reference to these preferred embodiments, other embodiments can achieve the same results. Variations and modifications of the present invention will be obvious to those skilled in the art and it is intended to cover all such modifications and equivalents. The various configurations that have been disclosed herein are intended to educate the reader about preferred and alternative embodiments, and are not intended to constrain the limits of the invention or the scope of the claims. The entire disclosures of all patents, references, and publications cited above are hereby incorporated by reference.

What is claimed is:

1. A photovoltaic module comprising:
a plurality of back-contact solar cells;
a flexible backsheet;
a patterned metallization on said backsheet;
an insulating material disposed between said patterned metallization and said solar cells, said insulating material patterned so as to enable electrical contact between said patterned metallization and said solar cells in desired locations; and
a plurality of busses in electrical contact with said patterned metallization.

2. The photovoltaic module of claim 1 further comprising a moisture barrier on said backsheet, said moisture barrier being sufficiently thin to enable roll-to-roll processing of said backsheet combined with said patterned metallization and said moisture barrier.

3. The photovoltaic module of claim 1 wherein said insulating material comprises an interlayer dielectric (ILD).

4. The photovoltaic module of claim 3 wherein said ILD comprises islands or dots.

5. The photovoltaic module of claim 3 wherein at least a portion of said ILD has been modified to change its appearance.

6. The photovoltaic module of claim 1 further comprising an encapsulant.

7. The photovoltaic module of claim 6 wherein said encapsulant comprises a thermoplastic material.

8. The photovoltaic module of claim 6 wherein said encapsulant comprises a scrim layer disposed between said solar cells and said patterned metallization.

9. The photovoltaic module of claim 6 wherein said insulating material comprises said encapsulant.

10. The photovoltaic module of claim 6 wherein said encapsulant is integrated with said backsheet prior to assembly of the module.

11. The photovoltaic module of claim 10 wherein said encapsulant and said backsheet are laminated together using roll-to-roll processing techniques.

12. The photovoltaic module of claim 1 wherein said limited electrical contact is provided by a material comprising a polymer matrix and conductive particles.

13. The photovoltaic module of claim 1 wherein said backsheet comprises one or more openings through which the busses are extended.

14. The photovoltaic module of claim 1 wherein at least a portion of one or more said busses are integrated with a trim strip prior to assembly of the module.

15. A photovoltaic module comprising:
a plurality of back-contact solar cells;
a first insulating backsheet;
a first patterned metallization in contact with a first face of said first insulating backsheet;
a second patterned metallization in contact with a second face of said first insulating backsheet;
an insulating material disposed between said first patterned metallization and said solar cells, said insulating material patterned so as to enable electrical contact between said first patterned metallization and said solar cells in desired locations; and
a second backsheet in contact with said second patterned metallization.

16. The photovoltaic module of claim 15 wherein said second backsheet comprises openings for said second patterned metallization to make electrical contacts external to said second backsheet.

17. The photovoltaic module of claim 15 wherein a portion of said first patterned metallization and a portion of said second patterned metallization comprise different areas of a foil wrapped around an edge of said first insulating backsheet.

18. The photovoltaic module of claim 15 wherein a portion of said first patterned metallization and a portion of said second patterned metallization are connected through at least one opening in said first insulating backsheet.

19. The photovoltaic module of claim 15 further comprising a plurality of flat pack bypass diodes.

20. The photovoltaic module of claim 15 further comprising a moisture barrier on said second backsheet, said moisture barrier being sufficiently thin to enable roll-to-roll processing of said backsheet combined with said second patterned metallization and said moisture barrier.

21. The photovoltaic module of claim 15 wherein said insulating material comprises an interlayer dielectric (ILD).

22. The photovoltaic module of claim 21 wherein said ILD comprises islands or dots.

23. The photovoltaic module of claim 21 wherein at least a portion of said ILD has been modified to change its appearance.

24. The photovoltaic module of claim 15 further comprising an encapsulant.

25. The photovoltaic module of claim 24 wherein said encapsulant comprises a thermoplastic material.

26. The photovoltaic module of claim 24 wherein said encapsulant comprises a scrim layer disposed between said solar cells and said patterned metallization.

27. The photovoltaic module of claim 24 wherein said insulating material comprises said encapsulant.

28. The photovoltaic module of claim 24 wherein said encapsulant is integrated with at least one said backsheet prior to assembly of the module.

29. The photovoltaic module of claim 28 wherein said encapsulant is laminated to at least one said backsheet using roll-to-roll processing techniques.

30. The photovoltaic module of claim 15 wherein said limited electrical contact is provided by a material comprising a polymer matrix and conductive particles.

31. A photovoltaic module comprising:
a plurality of back-contact solar cells;
a flexible backsheet;
a patterned metallization on said backsheet; and
a plurality of islands comprising an ILD material disposed between said patterned metallization and said solar cells.

32. The photovoltaic module of claim 11 further comprising a plurality of annuli comprising said ILD material, each annulus surrounding and containing a conducting material electrically connecting said solar cells and said patterned metallization.

33. The photovoltaic module of claim 32 wherein said conducting material comprises a polymer matrix and conducting particles.

34. A backsheet assembly for a photovoltaic module, the backsheet assembly comprising:
a flexible backsheet;
a patterned metallization; and
a moisture barrier sufficiently thin to enable roll-to-roll processing of said backsheet together with said second patterned metallization and said moisture barrier.

35. The backsheet assembly of claim 34 wherein said moisture barrier has a thickness of less than approximately 25 μm.

36. The backsheet assembly of claim 35 wherein said moisture barrier has a thickness of less than approximately 15 μm.

37. The backsheet assembly of claim 36 wherein said moisture barrier has a thickness of less than approximately 10 μm.

38. The backsheet assembly of claim 37 wherein said moisture barrier has a thickness of approximately 9 μm.

39. The backsheet assembly of claim 34 further comprising an ILD or an encapsulant laminated to said flexible backsheet or said patterned metallization.

40. A photovoltaic module comprising:
a plurality of back-contact solar cells;
a flexible backsheet;
a patterned metallization on said backsheet forming a plurality of circuits, each circuit connecting a subset of the solar cells, wherein at least one of said circuits comprises a non-linear circuit path; and
a plurality of cord plates in multiple locations on the module, each cord plate electrically comprising one or more bypass diodes for bypassing one or more of said circuits.

41. The photovoltaic module of claim 40 wherein said solar cells comprise upgraded metallurgical grade silicon or low-resistivity silicon.

42. The photovoltaic module of claim 40 wherein each bypass diode bypasses less than 20 solar cells.

43. The photovoltaic module of claim 42 wherein each bypass diode bypasses less than 16 solar cells.

44. The photovoltaic module of claim 43 wherein each bypass diode bypasses less than 11 solar cells.

45. The photovoltaic module of claim 44 wherein each bypass diode bypasses less than 7 solar cells.
